(19) United States
(12) Patent Application Publication
(10) Pub. No.: US 2008/0137308 A1
(43) Pub. Date: Jun. 12, 2008

(54) Thermal Management system and method for semiconductor lighting systems

(75) Inventors: Jamie A. MacDonald, Cambridge (CA); Ronald G. Hare, Belleville (CA)

Correspondence Address: WARN, HOFFMANN, MILLER & LALONE, .P.C, PO BOX 70098, ROCHESTER HILLS, MI, 48307, US

(73) Assignee: Magna International Inc., Aurora (CA)

(21) Appl. No.: 11/636,744

(22) Filed: Dec. 11, 2006

(51) Int. Cl. H05K 7/20

(52) U.S. Cl. 361/720

(57) ABSTRACT

A method and assembly for dissipating heat from semiconducting light sources. The light sources are connected to a circuit board with a plurality of layers. The waste heat produced by the semiconducting light source is transferred through the layers of the circuit board in order to dissipate the heat.

### FIELD OF THE INVENTION

The present invention relates to a method and system for dissipating heat produced by semiconductors.

### BACKGROUND OF THE INVENTION

Advances in semiconductor devices have resulted in semiconductor light sources, such as light emitting diodes (LEDs), having sufficiently high light output. This high output of the semiconductor light sources enables them to be employed as light sources in a variety of devices previously limited in incandescent and/or gas discharge light sources.

In particular, high output LEDs, which can typically output 100 lumens or more, can be used to create lighting devices such as automotive headlamps and/or indicator lights. Prior to the high output LEDs, LEDs did not emit a sufficient amount of light to be used as headlamps on motorized vehicles, or the like.

However, while such LED-based lighting devices offer numerous advantages over conventional lighting devices they do have some disadvantages. In particular, the operating lifetime of LEDs is limited by the semiconductor junction in the LEDs. The lifetime of the semiconductor junction is related to the temperature at which the junction operates. High output LEDs generate a significant amount of waste heat when operating which has an adverse affect on the durability of the semiconductor junction. Thus, as the waste heat is produced and continues to heat the semiconductor junction, the semiconductor junction deteriorates.

Therefore, it is desirable to develop a circuit board assembly for removing the waste heat from the semiconductor light sources.

### SUMMARY OF THE INVENTION

An embodiment of the present invention relates to a method for dissipating heat from a light source providing the steps of providing a circuit board, providing at least one light source connected to the circuit board, and dissipating the heat from the light source. The circuit board has a plurality of layers. The light source produces heat when the light source draws electrical current. The heat from the light source is dissipated by transferring the heat from a first layer of the circuit board, where the light source is connected, to a second layer of the circuit board.

Another embodiment of the present invention relates to a circuit board assembly for dissipating heat providing a circuit board and at least one light source. The circuit board has a plurality of layers. The light source is connected to a first layer of the circuit board. The heat produced from the light source is transferred from the first layer of the circuit board to a second layer of the circuit board.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1 is a schematic top view of a light source assembly in accordance with an embodiment of the present invention;

FIG. 2 is a cross-sectional plan view of a circuit board in accordance with an embodiment of the present invention;

FIG. 3 is a schematic chart of a method for dissipating waste heat from a light source in accordance with an embodiment of the present invention;

FIG. 4 is a cross-sectional plan view of another circuit board in accordance with an embodiment of the present invention; and

FIG. 5 is a schematic chart of a method for dissipating waste heat from a light source in accordance with an embodiment of the present invention.

### DETAILED DESCRIPTION OF THE PREFERRED EMBODIMENTS

The following description of the preferred embodiment(s) is merely exemplary in nature and is in no way intended to limit the invention, its application, or uses.

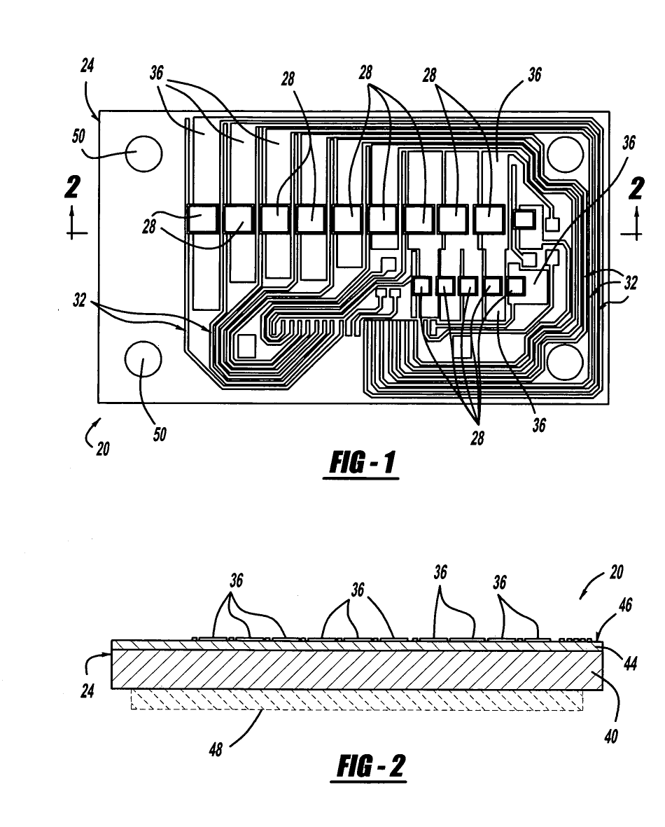

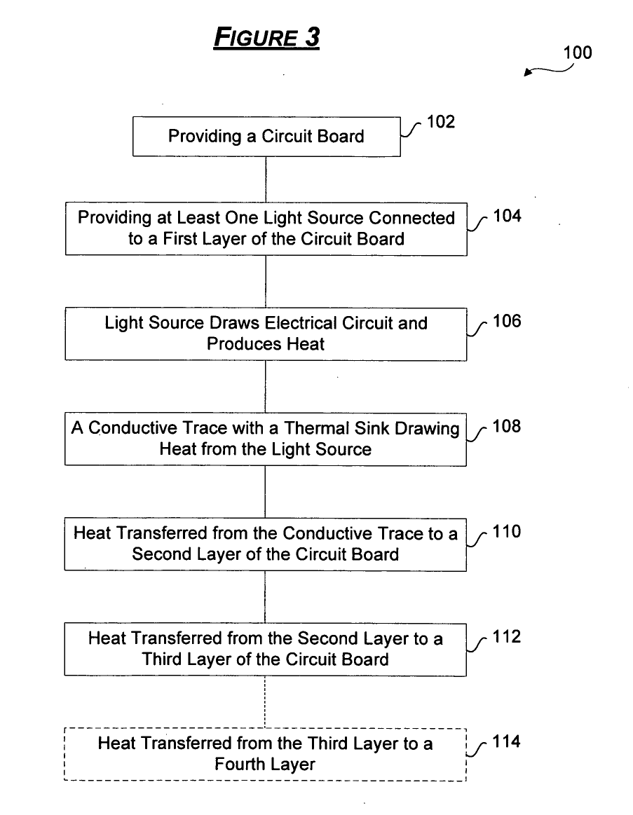

Referring to FIGS. 1 and 2, a light source assembly is generally shown at 20. The light source assembly 20 includes a circuit board generally indicated at 24, on which at least one semiconductor light source 28 is mounted. The light sources 28 can be, but are not limited to, light emitting diodes (LEDs). The light sources 28 are arranged in a variety of suitable patterns and/or spacings on the circuit board 24 depending upon the design of the light source assembly's 20 optics and the requirements for the beam pattern produced by the light source assembly 20.

The light sources 28 are interconnected and/or connected to a suitable power source (not shown) by conductive traces generally indicated at 32. The conductive traces 32 are fabricated from a material which is both electrically and thermally conductive. By way of explanation and not limitation, the conductive traces 32 can be made of such a material as copper or gold.

The light sources 28 are connected to a first layer or top circuit layer, generally indicated at 46, of the circuit board 24. The light sources 28 are connected to the top circuit layer 46 and to the conductive traces 32. The conductive traces 32 are connected to a power source and the light sources 28 to transfer power to the light sources 28.

At least one of each of the conductive traces 32 to which the light sources 28 are connected have a thermal sink area 36. The thermal sink area 36 is the portion of the conductive trace 32 that is adjacent the light source 28. The size of thermal sink areas 36 can be in excess of that required to carry electrical current to or from the light sources 28. The excessive size of the sink areas 36 are provided to draw heat from the operating light sources 28 and to transfer that heat to a second layer or thermal transfer layer 44 and to a third layer or thermal management layer 40 of circuit board 24, as described below.

While the total amount of heat produced by light sources 28 may not be excessive, the fact that the heat is produced in a very small area, at the semiconductor junction (not shown), results in very high thermal densities or concentrations. By way of explanation and not limitation, one watt of heat radiated from a surface area of a square centimeter may not be problematic in many circumstances, but when that one watt of heat is radiated from a surface area of one square millimeter the thermal density is the equivalent of one hundred watts of heat radiated from one square centimeter. High thermal densities cause damage to the semiconductor junction. Therefore, reducing the thermal density prevents failure of the semiconductor junction which otherwise renders the light source 28 inoperable. Avoiding high thermal densities reduces the deterioration of the semiconductor junction operating under high thermal density conditions.

The thermal sink areas 36 provide both a mass of thermally conductive material to draw waste heat from the operating light sources 28 and a relatively large surface area to enhance the transfer of heat from the light sources 28 to the thermal management layer 40. The reason for this is that one of the factors upon which the effectiveness of thermal transfer is dependent, is the surface area over which the transfer occurs. Therefore, a sink area 36 with a larger surface area than the light sources 28 dissipates the heat more efficiently than a thermal sink area 36 with a smaller surface area than the light sources 28. The material used for the thermal sink area 36 draws the heat from the light source 28 which results in maintaining a more desirable light source 28 temperature. The heat is then transferred across the heat sink area 36 to the thermal management layer 40 in order for the heat to be dissipated from the light source assembly 20.

The circuit board 24 includes the thermal management layer 40, the thermal transfer layer 44, and the top circuit layer 46. The thermal transfer layer 44 is made of an electrically insulating and thermally conductive material or the like. Also, the top circuit layer 46 includes the light sources 28, the conductive traces 32, and thermal sink areas 36.

The thermal management layer 40 can be fabricated from a material with a thermal transfer characteristic and can have significantly more mass than either of the top circuit layer 46 or the thermal transfer layer 44. Typically, the mass of the thermal management layer 40 is formed by the greater thickness of the thermal management layer 40 when compared to the thermal transfer layer 44 and the top circuit layer 46.

An example of a material used to form the thermal management layer 40 is, but not limited to, copper. By way of explanation and not limitation, an ideal thickness for the thermal management layer 40 is about 1.6 millimeters. The larger mass of the thermal management 40 allows for the waste heat transferred to the thermal management layer 40 to be dissipated quicker than if the heat remained in the semiconductor junction. It should be appreciated that the larger surface area of the thermal management layer 40 allows for the ambient air to contact the thermal management layer 40 over the large surface area; thus, cooling or dissipating the heat from the light source assembly 20.

The conductive traces 32, including the sink areas 36, are fabricated from a material with a thermal transfer characteristic or the like. An example of the material used for the conductive traces 32 and sink areas 36 is, but not limited to, copper. By way of explanation and not limitation, an ideal thickness for the conductive traces 32, including the sink areas 36 is about 0.1 millimeters. Thus, the conductive traces 32, including the sink areas 36, have different thicknesses than the thermal management layer 40, which allows the thermal management layer 40 to have a greater mass than the top circuit layer 46.

While in the disclosed embodiment the ratio between the thickness of thermal management layer 40 to the thickness of the top circuit layer 46 is about sixteen to one, it is within the scope of the present invention that ratios as low as two to one can be employed. However, the higher ratios between the thicknesses of the thermal management layer 40 and the top circuit layer 46 can be used because the greater the ratio the more heat the thermal management layer 40 can draw from the top circuit layer 46. This ultimately results in increasing the amount of heat dissipated and the efficiency of the heat dissipation from the light source assembly 20.

The thermal management layer 40 and the conductive traces 32 are not limited to being formed from copper. The thermal management layer 40 and conductive traces 32 can be made of other suitable materials and/or combinations of materials which have similar characteristics as the above described materials. By way of explanation and not limitation, the conductive traces 32 can be formed from gold or the like, while the thermal management layer 40 can be formed from copper, aluminum, or the like. The thermal management layer 40 can also be formed from non-metal materials such as graphite materials or the like. Examples of such a material are, but not limited to, the zSpreader™ material manufactured by GrafTech Advanced Energy Company, P.O. Box 94637, Cleveland, Ohio, or other advanced thermal materials which offer thermal transfer rates better than copper at a lower cost than gold.

The thermal transfer layer 44 is fabricated from any suitable material with appropriate electrical insulating properties to insulate conductive traces 32 from thermal management layer 40 and with appropriate thermal transmission properties to transmit heat from thermal sink areas 36 to thermal management layer 40. The thermal transfer layer 44 can be fabricated from a dielectric sheet, such as the 1KA dielectric sheets sold by Thermagon, Inc., 4707 Detroit Ave, Cleveland, Ohio, USA which is appropriately laminated to the thermal management layer 40 along with a top layer of electrically conductive material, such as copper or the like, from which the conductive traces 32 and the thermal sink areas 36 are fabricated. The Thermagon material includes a thermally conductive ceramic in an epoxy based pre-peg material which is laminated to the thermal management layer 40 and then baked to cure it. Other suitable materials for thermal transfer layer 44 include, without limitation, the T-Clad™ material sold by The Berquist Company, 18930 W. 78th Street, Chanhassen, Minn., the 99ML™ material sold by ARLON, 1100 Governor Lea Road, Bear, Del., or the like.

As waste heat is generated by the light sources 28, the waste heat is distributed over respective thermal sink areas 36 and then through the thermal transfer layer 44 to thermal management layer 40. The relatively large surface areas of thermal sink areas 36 enhance removal of heat from the light sources 28 and the transmission of that heat to thermal management layer 40 through thermal transfer layer 44.

In an alternate embodiment, the thermal management layer 40 is thermally connected to a fourth layer 48 (shown in phantom) for dissipating heat. By way of explanation and not limitation, the fourth layer can be a heat sink, heat pipe, or other heat dissipation mechanism. One or more mounting holes 50, are provided in circuit board 24 for effecting such a thermal connection. Thus, a suitable fastener extends through the hole 50 and into the thermal transfer layer 44 and thermal management layer 40. The connector can also extend into the fourth layer 48, when the fourth layer 48 is being used.

The thermal sink areas 36 can be formed as part of at least one of the conductive traces 32 to and/or from the light sources 28. Alternatively, the thermal sink area 36 can be in thermal connection with a respective light source 28 to transfer heat from the light sources 28. Thus, a pair of conductive traces 32 supply power to the light sources 28 while the thermal sink area 36 is electrically separate from the conductive traces 32 but in physical contact with the light sources 28.

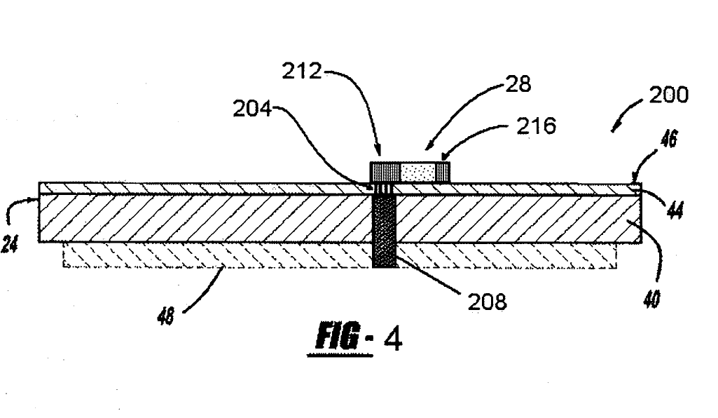

In reference to FIG. 3, a method for dissipating heat from a light source is generally shown at 100. The first step of the method 100 is to provide a circuit board, which is shown at decision box 102. Next, at least one light source is connected to a first layer of the circuit board, which is shown at decision box 104. At decision box 106, the light source draws an electrical circuit from a power source and produces heat. Typically, the light sources also produce waste heat as the light source is operating to emit light.

The circuit board also has a conductive trace which has a thermal sink connected to the first layer of the circuit board. The conductive trace and thermal sink draw the heat from the light source, which is shown at decision box 108. At decision box 110, the heat transferred from the light source to the conductive trace is then transferred to a second layer of the circuit board. Thereafter, the heat transferred to the second layer is transferred to a third layer of the circuit board, which is shown at decision box 112. Thus, the heat is dissipated from the light source when the heat is transferred to the third layer. Further, the third layer is typically formed with a surface area which allows for the third layer to dissipate the heat.

In an alternate embodiment, the circuit board has a fourth layer. Heat is then transferred from the third layer to the fourth layer, which is shown at decision box 114 (shown in phantom). The heat transferred to the fourth layer is dissipated in a similar fashion as described in decision box 112.

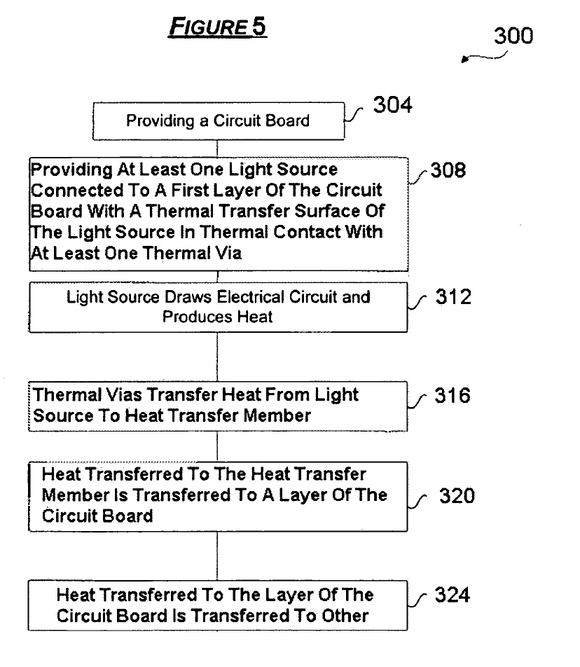

Another embodiment of the present invention is indicated generally at 200 in FIG. 4, wherein like components to those of FIGS. 1 and 2 are indicated with like reference numerals. In this embodiment, a set of thermal vias 204 are formed through circuit layer 46 and thermal transfer layer 44. A heat transfer member 208, such as, but not limited to, an aluminum rivet or the like, extends through and contacts thermal management layer 40 and fourth layer 48, if present. Alternatively, heat transfer member 208 can be a boss or other feature formed on fourth layer 48. It is contemplated that fourth layer 48 can be a cast or machined heat sink or the like and in such a case heat transfer member 208 can be a rivet set in fourth layer 48 or can be a feature formed in fourth layer 48.

As shown in the Figure, light source 28 includes a first electrical contact 212 and a second electrical contact 216 each of which are electrically connected to different ones of the circuit traces of circuit layer 46 by any suitable way of attachment, such as, but not limited to, surface mount soldering or the like, to supply electrical current to light source 28. As is also shown in the Figure, first electrical contact 212 is somewhat larger than second electrical contact 216 as light source 28 is constructed by its manufacturer such that first electrical contact 212 is also intended to serve as a primary heat transfer surface to remove waste heat from light source 28.

Accordingly, light source 28 is mounted to circuit layer 46 such that first electrical contact 212 is in thermal contact with thermal vias 204 which, in turn, are in thermal contact with heat transfer member 208. As should now be apparent to those of skill in the art, waste heat is transferred, by thermal vias 204, from light source 28 to heat transfer member 208. This waste heat is conducted along heat transfer member 208 and to thermal management layer 40 and to fourth layer 48, if present. If thermal management layer 40 is formed of a material with anisotropic properties, such as the zSpreader™ material mentioned above, such material can be oriented to enhance the transfer of heat away from heat transfer member 208 and into thermal management layer 40, and then to fourth layer 48 or another heat sink layer or device.

As should now be apparent to those of skill in the art, the embodiment of FIG. 4 does not require a thermal sink area, such as thermal sink area 36 of FIGS. 1 and 2, and thus light sources 28 can be more closely spaced and/or light assembly 200 can be smaller than would otherwise be required as surface area is not required for thermal sink areas 36.

As should also be apparent, the thickness of thermal transfer layer 44 can be much reduced from that of the embodiment shown in FIGS. 1 and 2, as thermal vias 204 provide an effective heat transfer to heat transfer member 208 and thermal management layer 44. In a present implementation of this embodiment of the invention, thermal transfer layer is on the order of 0.005 of an inch in thickness (0.128 millimeters).

In reference to FIG. 5, a method for dissipating heat from a light source is generally shown at 300. The first step of the method 300 is to provide a circuit board, which is shown at decision box 304.

Next, at least one light source is connected to a first layer of the circuit board such that a thermal transfer surface of the light source is in thermal contact with one or more thermal vias through the layer of the board to which the light source is mounted, which is shown at decision box 308. At decision box 312, the light source draws an electrical circuit from a power source and produces light. Typically, the light sources also produce waste heat as the light source is operating to emit light.

The circuit board includes a thermal transfer member in thermal contact with the thermal vias through the first layer of the circuit board. The thermal vias draw the heat from the light source to the thermal transfer member, which is shown at decision box 316.

At decision box 320, the heat transferred from the light source to the heat transfer member is then transferred to a second layer of the circuit board. Thereafter, the heat transferred to the second layer is transferred to at least a third layer of the circuit board, which is shown at decision box 324. Thus, the heat is dissipated from the light source when the heat is transferred to at least the third layer.

The description of the invention is merely exemplary in nature and, thus, variations that do not depart from the gist of the invention are intended to be within the scope of the invention. Such variations are not to be regarded as a departure from the spirit and scope of the invention.

What is claimed is:

1. A method for dissipating heat from a light source comprising the steps of:
providing a circuit board having a plurality of layers;
providing at least one light source connected to a first layer of said circuit board, wherein said at least one light source produces heat when said at least one light source draws electrical current; and
dissipating said heat from said at least one light source by transferring said heat from said first layer to a second layer of said circuit board.

2. The method of dissipating heat from a light source of claim 1, wherein said second layer is a thermal transferring layer formed by a material that is an electrical insulator and a thermal conductor.

3. The method of dissipating heat from a light source of claim 1 further comprising the step of transferring said heat from said second layer to a third layer.

4. The method of dissipating heat from a light source of claim 3, wherein said third layer is a thermal management having a greater thickness than said first layer and said second layer, such that said heat is dissipated over the surface area of said third layer.

5. The method of dissipating heat from a light source of claim 3, wherein said third layer is formed of a material with a high thermal conductivity.

6. The method of dissipating heat from a light source of claim 3 further comprising the step of providing a fourth layer connected to said third layer, wherein said fourth layer is a heat sink, such that said heat is transferred to said heat sink from said third layer in order to dissipate said heat.

7. The method of dissipating heat from a light source of claim 1 further comprising the step of providing at least one conductive trace connecting said light source to said circuit board.

8. The method of dissipating heat from a light source of claim 7 further comprising the step of providing a thermal sink as part of said conductive trace, wherein said thermal sink draws said heat from said light source, such that said heat from said light source is transferred from said light source through said thermal sink to said second layer.

9. The method of dissipating heat from a light source of claim 1 wherein said first layer includes at least one thermal via to facilitate the transfer of heat from the light source to a thermal transfer member extending through at least one other layer of the circuit board, the at least one thermal via and the thermal transfer member transferring heat from the light source to the at least one other layer of the circuit board.

10. A light source assembly for dissipating heat comprising:
a circuit board having a plurality of layers;
at least one light source connected to a first layer of said circuit board; and
a second layer operably connected to said at least one light source, wherein heat produced from said light source is transferred to said second layer.

11. The light source assembly of claim 10 further comprising at least one conductive trace connecting said at least one light source to said first layer.

12. The light source assembly of claim 11, wherein said conductive trace has at least one thermal sink, wherein said at least one thermal sink draws heat from said light source and transfers heat to said second layer.

13. The light source assembly of claim 10, wherein said second layer is a thermal transferring layer formed by a material that is an electrical insulator and a thermal conductor.

14. The light source assembly of claim 10 further comprising a third layer connected to said second layer.

15. The light source assembly of claim 14, wherein said third layer is a thermal management layer having a greater thickness than said first layer and said second layer, such that said heat is dissipated over the surface area of said third layer.

16. The light source assembly of claim 14, wherein said third layer is formed of a material with a high thermal conductivity.

17. The light source assembly of claim 14 further comprising a fourth layer connected to said third layer, wherein said fourth layer is a heat sink.

18. The light source assembly of claim 10 further comprising at least one thermal via extending through the first layer and a thermal transfer member extending through at least the second layer of the circuit board and being in thermal contact with the at least one thermal via, the thermal via thermally connecting the at least one light source to the thermal transfer member.

19. A light source assembly for dissipating heat comprising:
a circuit board having at least a first layer, a second layer, and a third layer;
at least one light source connected to said first layer of said circuit board;
said second layer of said circuit board operably connected to said at least one light source, wherein heat produced from said at least one light source is transferred from said first layer to said second layer; and
said third layer connected to said second layer, wherein heat produced from said at least one light source is transferred from said first layer, through said second layer, and to said third layer.

20. The light source assembly of claim 19 further comprising a fourth layer connected to said third layer, wherein said fourth layer is a heat sink.

21. The light source assembly of claim 19 further comprising at least one conductive trace connecting said light source to said circuit board.

22. The light source assembly of claim 21, wherein said conductive trace comprises a thermal sink, wherein said at least one thermal sink draws heat from said light source and transfers heat to said second layer.
